(19) United States
(12) Patent Application Publication
(10) Pub. No.: US 2012/0091988 A1
(43) Pub. Date: Apr. 19, 2012

(54) Remote machine sentinel

(76) Inventor: Kenneth Allen Barrett, Montgomery, AL (US)

(21) Appl. No.: 12/925,150

(22) Filed: Oct. 15, 2010

(51) Int. Cl. G01R 19/00

(52) U.S. Cl. 324/76.11

(57) ABSTRACT

A new and improved system that monitors electrically powered equipment. A device that is comprised of a current sensing device(s), a multiple channel transmitter, and a remote receiver carried by the operator. Said device alerts the operator via said remote receiver by audio, light, and or vibration as to the status of the machine. Said device can be used on a wide range of machines using a wide range of voltages. The said current sensing device can also be replaced with the said transmitter connected to the said machine(s)' controls which could energize the said transmitter as the said machine (s) ceases operation.

### FIELD OF INVENTION

The present invention relates to machines that run through cycles to perform a task and/or machines that must operate without failure. The present invention monitors the operation of the machine and alerts the operator if the machine has completed its cycle or has stopped.

Said invention can be used with any type of electrically operated machines.

### GENERAL: BACKGROUND OF INVENTION

The present invention relates to a remote alarm device for electrically powered equipment and more particularly, pertaining to signaling a person that a cycle has been completed by one of the monitored machines.

Typically an operator will load a machine to be operated through a predetermined cycle or length of time. Once a cycle has ended, the machine turns off.

Some machines are equipped with alarms or buzzers that sound once the cycle has ended. Often times these machines are located in remote areas of factories, homes, or wherever, thereby preventing the operators from hearing the buzzer or alarm. Thus, the operator is unaware that the machine cycle is completed which can be important in some instances.

What is needed is a way to notify the operator that the equipment's cycle is completed. A simple device for the operator to carry on his person while the machine is in operation that would notify him when the cycle has been completed would be an optimum solution.

The Present Invention solves the above mentioned problem by providing a device that is comprised of a current sensing mechanism coupled with a transmitter and a corresponding receiver carried by a person. Said transmitter is powered via a power sensing adapter placed between a power source and the equipment.

### BRIEF SUMMARY OF INVENTION

This apparatus is a remote alarm device for electrically powered operating equipment. Said alarm device is comprised of a current sensing device, a transmitter and remote receiver. Said transmitter is multi-channeled to accept the sensing of multiple machines (Said sensing device is not limited to a particular current or voltage and acts upon the drop of current).

Said sensing mechanism is capable of operating on a wide range of voltages. When current flow discontinues, said transmitter energizes the receiver. The Receiver System is portable and of compact design so as to be comfortable to be carried on a person. Said receiver is multiple channeled which is capable of energizing the alerting/alarming mechanisms.

In contrast to prior art, this present invention works with any electrically operated machine (s) with a multiple channeled transmitter which will accept the sensing of multiple machines, and the sensing device is not limited to a particular current or voltage and acts upon the drop of current.

The said device utilizing only the said transmitter and said receiver can be interfaced with the said machine (s) controls without the use of the current sensing devices to indicate the operational status of the said machine (s).

With regard to prior art, most of the similar devices that have to do with remote receivers are associated with washing machines or dryers. The said present invention described here, as has been stated, will work with any electrically operated machine (s). Also, the said present invention has said multiple channel transmitter and the said multiple channel receiver which gives the option of having an almost unlimited numbers of said remote receivers from different said machines or the same said machine, according to the need.

By way of example, U.S. Pat. No. 6,424,252 to Adler discloses a paging system for washers and dryers that include a remote control device, a transmitter, and some type of means of detecting end of cycle. There is mention of a plurality of function buttons on the transmitter and receiver, but there is no explanation what their functions are. This device by Adler also is described as having a function button (16) that relates to setting timers and time of day. This present said invention substantially departs from Adler's paging system by not have plurality of function buttons and timer buttons, or utilizing time of day. This present said invention also is much more user friendly with regards to the set-up with the connections to the machine (s), to the said transmitter, and use of the said remote receiver. The Adler system does not indicate how the transmitter is connected to the machines in order that the end of cycle could be detected. The present said invention describes and shows through the attached figures how the connections are made between the said transmitter and the said machine (s) and how the end of cycle is detected. The present said invention also is constructed so that if can be used with any electrically operated said machine (s), and not just a washer or dryer.

U.S. Pat. No. 4,916,439 to Estes discloses a wireless remote device for indicating the status of a washing machine or dryer through the use of a current sensor, vibration sensor, or a sensor integral with the washing machine controls. U.S. Pat. No. 4,797,656 to Keppler discloses an appliance paging system which uses an inside the dryer duct humidity sensor. U.S. Pat. No. 5,757,643 to Kuroda discloses a remote management system for a number of washing machines and dryers. U.S. Pat. No. 5,285,375 to Kim discloses a remote control system for a washing machine. U.S. Pat. No. 5,089,809 to Carmichael, Jr. discloses means for monitoring the status of a number of different appliances.

While these devices fulfill their respective, particular objectives and requirements, the said patents discussed above do not adequately describe or illustrate a system for washers or dryers, or any other appliance or machine or machines that would signal an operator that the said machine (s) had ceased operation in a simple and user friendly design as does the said present invention.

The present said invention of a remote machine sentinel is significantly different from the prior art mentioned above in their conventional concepts and designs, and is more flexible, simpler in design, more user friendly, easier to install, and provides a simple alert signal at the cessation of operation of the said machine (s) that are monitored. The said present invention also notifies the operator when said operator is out of range of the alert signal, which differs from the aforementioned prior art.

The said present invention is easily built from normally available parts, and can be manufactured in mass easily and efficiently, with a relatively low cost with regard to materials and labor, thus making said invention economically available to the general public.

### BRIEF DESCRIPTION OF SEVERAL VIEWS OF THE DRAWINGS

For a further understanding of the nature, objectives, and advantages of the present invention, reference should be made to the following detailed description, read in conjunction with the following drawings, wherein like reference numerals denote like elements:

### Description of Figures

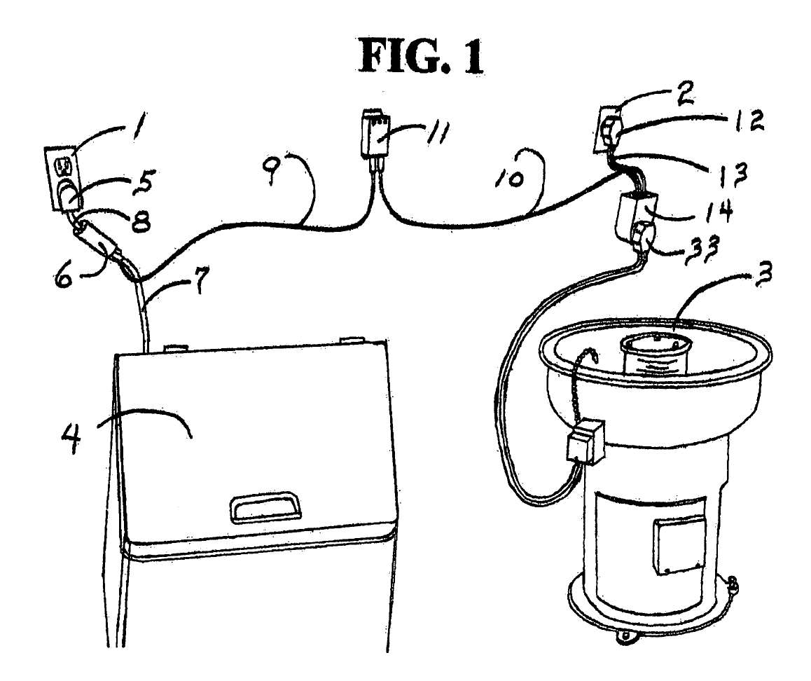

FIG. 1 Perspective view of remote cycle sensing detection device attached to machine (s).

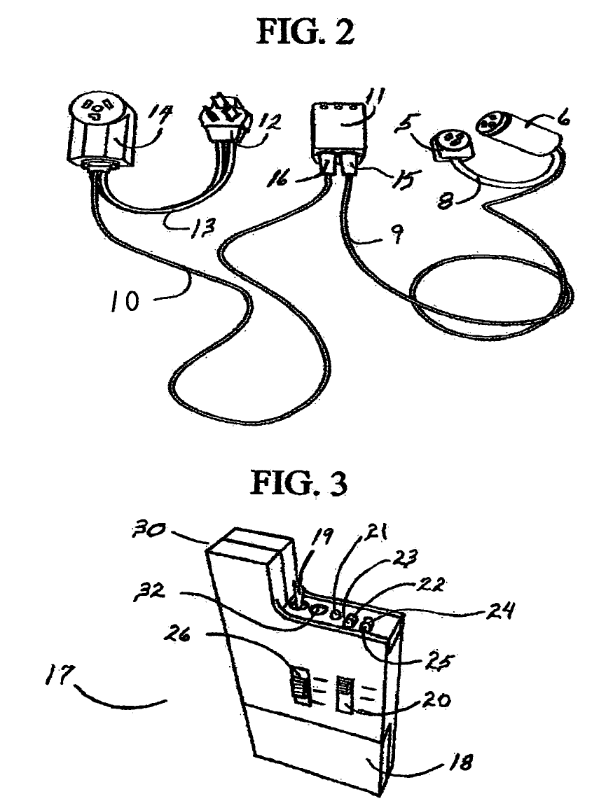

FIG. 2 Perspective view of selective detection multiple channel transmitter with attached current sensors.

FIG. 3 Perspective view of multiple channel receiver.

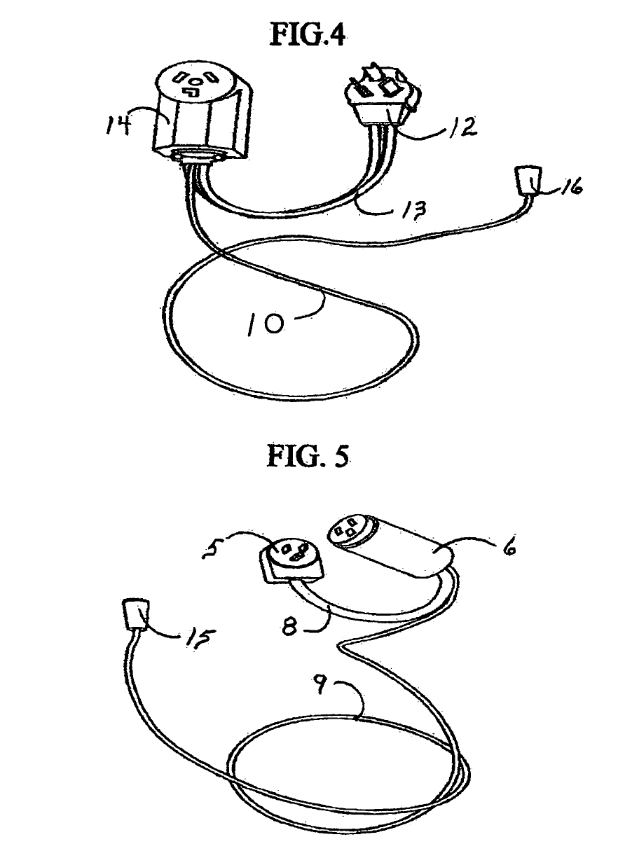

FIG. 4 Perspective view of a high current sensing device.

FIG. 5 Perspective view of a low current sensing device.

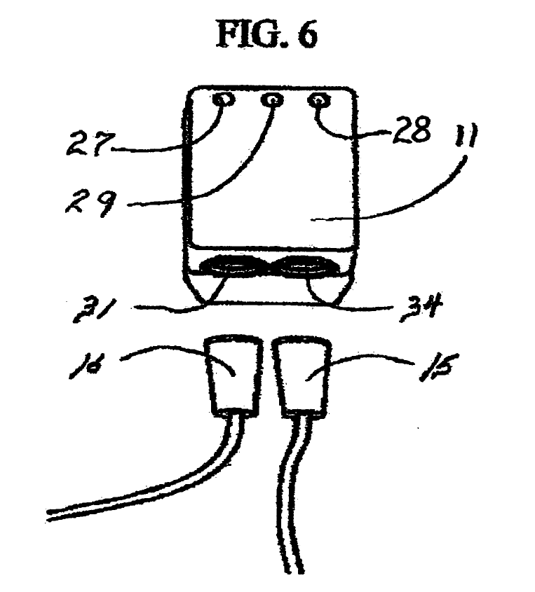

FIG. 6 Perspective view of selective detection multiple channel transmitter with current sensor signal cable with twist lock connectors.

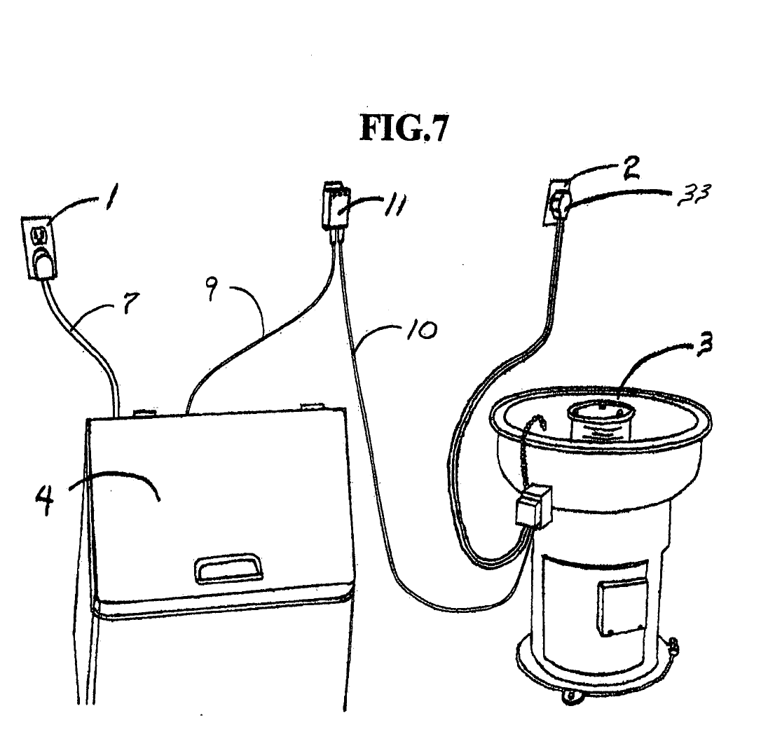

FIG. 7 Perspective view of selective detection multiple channel transmitter directly connected to the controls of the machines, thus eliminating the need for the current sensing device (s).

### DETAILED DESCRIPTION OF THE PREFERRED EMBODIMENT OF THE INVENTION

To further describe the function and relationship of components, attention should be given to the following detailed description where alike numbers denote like components noted in the different figures, along with the description and explanation of each. To best describe the operation and function of the invention, attention should be given to FIG. 1, a frontal view of the system installed on a typical electrically operated device, where number 4 represents a machine that is operated on 120 volt typical household current; and number 3 represents a machine that operates on 240 volt current typically found in homes and factories (It should be noted that this device can be utilized to sense any voltage and is not limited by respective components).

Number 1, in FIG. 1, represents a typical 120 volt electrical receptacle found in homes and factories. Number 2 in FIG. 1, is a typical 240 volt receptacle found in homes and factories.

In general the system is comprised of a current sensing device, a transmitting unit, and a remote receiver.

To further describe the relationship between the individual components of the apparatus, attention should be given to the current sensing units best depicted in FIG. 4 and FIG. 5.

FIG. 4 is a perspective view of the 240 volt or also referred to as the “high current sensing unit.” The high current sensing unit is further described by giving attention to number 12, the 240 volt plug in FIG. 4, and number 13, the 240 volt interconnect cable between the plug and the current sensor, number 14, the 240 volt current sensor with receptacle, number 10, the high current sensor signal cable to the transmitter, and number 16, the high current sensor signal cable with twist lock connector.

To further describe the function of FIG. 4, the high current sensing unit, attention should be given to FIG. 4 in conjunction with FIG. 1, where number 33, the 240 volt machine power cord with plug, is plugged into number 14, the 240 volt current sensor with receptacle.

To further understand the high current sensing unit, number 12, the 240 volt plug in FIGS. 1 and 4, is inserted into number 2, the 240 volt wall receptacle of FIG. 1, which provides power through number 12, the 240 volt plug, number 13, the 240 volt interconnecting cable, and number 14, the 240 volt current sensor with receptacle, to number 33, the 240 volt machine power cord, which energizes number 3, the 240 volt controlled machine of FIG. 1.

To further understand the benefits and features of the monitoring system it should be understood that the current sensing device is one way to determine the operational status of the machine(s), however, the transmitter/receiver devices can be interfaced with the machines controls (see FIG. 7) without the use of the current sensing devices, so that the transmitter can be energized during the machine's operation, thus monitoring the status of the machine.

It should be further understood that the system is not limited to the described combination of 240 volt or 120 volt machines. Any combination of only 120 volt or 240 volt equipment (such as computers, stereos, N's, industrial machines, etc.) is also recognized by the transmitter/receiver system.

### LIST OF PARTS TYPICALLY FOUND IN THE PRESENT INVENTION

(1) 120 volt wall receptacle (FIG. 1)
(2) 240 volt wall receptacle (FIG. 1)
(3) 240 controlled machine (FIG. 1)
(4) 120 volt controlled machine (FIG. 1)
(5) 120 volt plug on low current circuit (FIGS. 1, 2, and 5)
(6) 120 volt current sensor with receptacle (FIGS. 1, 2, and 5)
(7) 120 volt machine power cord with plug (FIG. 1)
(8) Low current interconnect cable between plug and current sensor (FIGS. 1, 2, and 5)
(9) 120 volt low current sensor signal cable to transmitter (FIGS. 1, 2, and 5)
(10) 240 volt high current sensor signal cable to transmitter (FIGS. 1, 2, and 4)
(11) Selective detection multiple channel transmitter (FIGS. 1, 2, and 6)
(12) 240 volt plug on high current circuit (FIGS. 1, 2, and 4)
(13) 240 volt interconnect cable between plug and current sensor (FIGS. 1, 2, and 4)
(14) 240 volt current sensor with receptacle (FIGS. 1, 2, and 4)
(15) 120 volt low current sensor signal cable with twist lock connector (FIGS. 2, 5, and 6)
(16) 240 volt high current sensor signal cable with twist lock connector (FIGS. 2, 4, and 6)
(17) Multiple channel receiver (FIG. 3)
(18) Battery cover (FIG. 3)
(19) Power on/off switch (FIG. 3)
(20) Three position alert switch (FIG. 3)
(21) Power on indicator (Green light) (FIG. 3)
(22) Channel 1 signal receiver indicator light for the 240 volt controlled machine (Yellow blinking means signal is being received) (FIG. 3)
(23) Channel 1 signal receiver indicator light for the 240 volt controlled machine (Red light means machine has stopped) (FIG. 3)
(24) Channel 2 signal receiver indicator light for the 120 volt controlled machine (Yellow blinking means signal is being received) (FIG. 3)
(25) Channel 2 signal receiver indicator light for the 120 volt controlled machine (Red light means machine has stopped) (FIG. 3)
(26) Three position apparatus selector switch (Operator can choose to monitor the 120 volt machine, or the 240 volt machine, or both at the same time) (FIG. 3)
(27) Channel 1 transmitter indicator light for the 240 volt controlled machine (Green light means machine is operating (FIG. 6)
(28) Channel 2 transmitter indicator light for the 120 volt controlled machine (Green light means machine is operating (FIG. 6)
(29) Blinking yellow light indicates that transmitter is operating) (FIG. 6)
(30) Internal antenna (FIG. 3)
(31) High current sensor cable receptacle on transmitter (FIG. 6)
(32) Audio portal (FIG. 3)
(33) 240 volt machine power cord with plug (FIG. 1)
(34) Low current sensor cable receptacle on transmitter (FIG. 6)

What is claimed:

1. A device that indicates the operational status of an electrically powered machine (s) which is comprised of an in-line current sensor system which is placed between the power source and the electrically powered machine and a multi-channeled transmitter that sends pulse signals to a multi-channel receiver or receivers with selective alarming mechanisms;
(a) whereas, the said device of claim 1 has the said sensor circuit which can be placed between a power source and said electrically powered device, or contained within the housing of the said electrically powered device, where current can be detected to as low as 6 watts;
(b) whereas, in said device of claim 1, said transmitter is pulse transmitting and the said receiver has a time delay between the end of the transmitted pulses before actuating at least one said alert mechanism;
(c) whereas, said device of claim 1 has the said receiver having selectable alert positions, including, but not limited to, an audio signal, a vibrating signal, and a light indicator, or all three at once.

2. Said device of claim 1 indicates the operational status of said electrical machine or machines which is comprised of said multiple channel transmitter, interfaced with the timing controls of the protected said machine or machines which sends pulse signals to said portable multiple channel receiver.

3. Said device of claim 1 or 2 where the said receiver mechanism indicates if operation is within an acceptable range or distance by said indicator light.

4. The said device of claim 1 indicates the operational status of said electrical device or devices, which is comprised of an in-line current sensor system which is placed between the power source and the electrically powered device, and said multi-channeled transmitter that sends pulse signals to said multi-channel receiver or receivers with said selective alarming mechanisms; (a) also, the said transmitter of claim 1 is protected from cross phasing by receiving operating power through only one of the said transmitter connectors;
(b) said device of claim 1 can consist of multiple said receivers which can simultaneously receive signals from said transmitter monitoring a number of different said machines.

5) The said transmitter and said receiver devices of claim 1 can be interfaced with the said machine(s) controls without the use of the said current sensing device, so that the said transmitter will be energized during the said machine(s) operation, thus monitoring the status of the said machine(s).
